(19) United States
(12) Patent Application Publication
(10) Pub. No.: US 2011/0168236 A1
(43) Pub. Date: Jul. 14, 2011

(54) PORTABLE PHOTOVOLTAICS WITH SCALABLE INTEGRATED CONCENTRATOR OF LIGHT ENERGY

(76) Inventors: Winston Kong Chan, Princeton, NJ (US); Michael G. Kane, Skillman, NJ (US)

(21) Appl. No.: 12/785,070

(22) Filed: May 21, 2010

Related U.S. Application Data
(60) Provisional application No. 61/187,435, filed on Jun. 16, 2009.

(51) Int. Cl. H01L 31/055; H01L 31/0216; H01L 31/0232

(52) U.S. Cl. 136/247; 438/73; 136/257; 438/94; 257/E31.119

(57) ABSTRACT

A luminescent solar concentrator (LSC) for receiving electromagnetic radiation of at least a first wavelength is disclosed. The LSC includes a core layer. A lower clad layer substantially underlies the core layer. At least one photovoltaic (PV) cell is partially embedded in at least one of the core layer and the lower clad layer. At least one dye layer substantially overlies the core layer. The at least one dye layer has embedded therein at least one absorption dipole and at least one emission dipole, the at least one emission dipole being coupled to the at least one absorption dipole. The at least one absorption dipole is configured to absorb the electromagnetic radiation of at least a first wavelength incident from any direction and the at least one emission dipole is configured to emit electromagnetic radiation of at least a second wavelength substantially within at least one of the core layer and the lower clad layer so that the electromagnetic radiation of at least a second wavelength is at least partially absorbed by the at least one PV cell. The at least one absorption dipole is coupled to the at least one emission dipole by Forster resonant energy transfer (FRET).

### CROSS-REFERENCE TO RELATED APPLICATIONS

This application claims the benefit of U.S. provisional patent application No. 61/187,435 filed Jun. 16, 2009, the disclosure of which is incorporated herein by reference in its entirety.

### FIELD OF THE INVENTION

The present invention relates generally luminescent solar concentrators (LSC), and more particularly, to an integrated solar-concentrator/solar-cell-module that collects solar radiation over a large area and over a large angle and routes this solar energy to small patches of solar cells integrated into the concentrator for photovoltaic power generation.

### BACKGROUND OF THE INVENTION

Solid state solar energy photovoltaics (PV) have existed for decades for use in energy generation for space exploration and military applications, and for generating supplemental energy in homes as a clean alternative to fossil fuels. Highly-efficient, cost-effective, light-weight, flexible, and durable solar energy photovoltaics are particularly desirable for military applications where there is a strong need for available portable power generated from PV systems to reduce the supply chain as well as to enable new Department of Defense field missions such as PV-integrated shelters and smart power skins.

Photovoltaics include one or more cells or arrays of cells containing a solar photovoltaic material that converts solar radiation into direct current electricity. Materials presently used for photovoltaics include monocrystalline silicon, polycrystalline silicon, microcrystalline silicon, cadmium telluride, and copper indium selenide/sulfide. While traditional single-crystal, semiconductor PVs may have conversion efficiencies of upwards of 20%, such first generation semiconductor PVs have high manufacturing costs largely due to the expense of producing purified PVs for covering large areas for collection of photons. First generation semiconductor PVs also have inflexible substrates.

Second generation, thin-film PVs have certain advantages over first generation PVs, including having a lower cost, being overall thinner, and for some realizations being flexible. Thin film PV, while less expensive than silicon, have efficiencies ranging from a few percent, thereby requiring larger areas to produce the same amount of electricity compared to smaller silicon solar cells to a few percentage points below that of crystalline silicon.

One solution to this problem currently being pursued is the use of solar trackers. These are moving panels of PV cells that trace the sun across the sky, so that sunlight is nearly normal to the panels throughout the day and from season to season. While more sunlight enters the cells using solar trackers, the resulting system is both expensive and complicated.

Another solution to the efficiency problem in solar panels is the solar concentrator (SC). An SC takes the sunlight that strikes a wide area and concentrates it into a smaller area, preferable the area covered by one or more first or second generation PVs. The main components in the traditional design of an SC are solar cells, lenses, often plastic Fresnel lenses, that focus the sunlight onto the solar cells, and a mechanical structure that maintains optical alignment.

In an SC, the concentration ratio (lens area to PV cell area) is typically several hundred to one. Each solar cell is exposed to sunlight collected by a much larger lens, meaning fewer silicon cells are needed and thus costs are lower.

There are drawbacks to the traditional design of SCs. The higher the concentration ratio, the more sensitive the SC is to alignment to the sun. This requires much more accurate tracking than in non-SC systems. The SC is designed to collect and focus direct sunlight, so its performance on overcast or hazy days is particularly poor. Finally, the PV cells must be actively cooled because of the large amount of waste heat even when employing high efficiency PV cells.

A variation of the SC is the luminescent solar concentrator (LSC). Unlike conventional solar panels which require 100% PV coverage (limiting cost, flexibility, puncture resistance, and weight), an LSC architecture is beneficial because of the sparse usage of PV cells. The traditional LSC is composed of two main components: a transparent sheet of glass or plastic embedded with fluorescent dyes that convert sunlight into fluorescence that is trapped in the optical waveguide formed by the transparent sheet, and solar cells butt coupled to the edges of the sheet that converts the fluorescence that has propagated to the periphery of the sheet to electricity.

Unfortunately, traditional LSCs suffer from low efficiency of waveguide fluorescent light capture, high Fresnel losses at the air/waveguide interface as well as at the waveguide/PV interface, sensitivity of waveguiding efficiency to environmental effects, and the difficulty of aligning/packaging PV cells at LSC edges. The coupling of light into a waveguide had been much lower than expected. As a result, current LSC modules only achieve about a 5% efficiency, and the placement of PV cells along the LSC edge, normal to the slab waveguide layer, results in limitations to integration, scalability and high-volume manufacturing.

Accordingly, what would be desirable, but has not yet been provided, is an efficient LSC design which overcomes the limitations of traditional LSCs outlined above.

### SUMMARY OF THE INVENTION

The above-described problems are addressed and a technical solution is achieved in the art by providing a luminescent solar concentrator (LSC) for receiving electromagnetic radiation of at least a first wavelength, comprising: a core layer; a lower clad layer substantially underlying the core layer; at least one photovoltaic (PV) cell partially embedded in at least one of the core layer and the lower clad layer; and at least one dye layer substantially overlying the core layer, the at least one dye layer having embedded therein at least one absorption dipole and at least one emission dipole, the at least one emission dipole being coupled to the at least one absorption dipole; wherein the at least one absorption dipole is configured to absorb the electromagnetic radiation of at least a first wavelength incident from any direction and the at least one emission dipole is configured to emit electromagnetic radiation of at least a second wavelength substantially within at least one of the core layer and the lower clad layer so that the electromagnetic radiation of at least a second wavelength is at least partially absorbed by the at least one PV cell. The LSC may further comprise an upper clad layer substantially overlying the at least one dye layer. The at least one absorption dipole may be coupled to the at least one emission dipole by Forster resonant energy transfer (FRET). The at least one emission dipole may aligned substantially perpendicular to a plane of stacking of the core layer, at least one dye layer, and the lower clad layer. The at least one absorption dipole may be substantially randomly aligned to a plane of stacking of the core layer, the at least one dye layer, and the lower clad layer.

According to an embodiment of the present invention, the at least one dye layer may comprise a plurality of dye layers that are sensitive to non-overlapping bands of electromagnetic radiation. Dipole dye molecules embedded within one of the plurality of dye layers may be configured to emit a wavelength of electromagnetic radiation that is within an absorption band of dipole dye molecules embedded within a successive layer of the plurality of dye layers. The plurality of dye layers may comprise at least a UV-blue emitting layer, a green emitting layer, and a red emitting layer.

According to an embodiment of the present invention, the upper clad layer, the at least one dye layer, the core layer, and the lower clad layer may have indices of refraction set to predetermined values such that the emitted electromagnetic radiation of at least a second wavelength is substantially confined within the core layer. At least one of the upper clad layer, the at least one dye layer, the core layer, and the lower clad layer may be composed of fluorinated polymers. At least one of the core layer and the lower clad layer may be configured to evanescently and/or butt couple the emitted electromagnetic radiation of at least the second wavelength to the PV cell.

According to an embodiment of the present invention, the at least one PV cell may be InP—InGaAsP based. The at least one PV cell may further comprise: an InP substrate of a first conductivity type; a lightly doped InGaAsP base layer of the first conductivity type at least partially underlying the InP substrate; and an InGaAsP emitter layer of a second conductivity type at least partially underlying the lightly doped InGaAsP base layer. The InP substrate may be thinned or completely removed. The at least one PV cell may be a plurality of PV cells arranged in a sparse hexagonal pattern and interconnected by at least one set of metallic interconnections in a series-parallel configuration to form effectively a single equivalent PV cell. The series-parallel configuration may include at least one chain of PV cells having at least one bypass diode to allow the chain of PV cells to operate at its maximum power point.

According to an embodiment of the present invention, the LSC may further comprise: a metal-1 layer substantially underlying the at least one PV cell and at least partially underlying the lower clad layer; a metal-1 fill layer substantially underlying the lower clad layer adjacent to the at least one PV cell; a dielectric layer substantially underlying the metal-1 layer; a metal-2 layer substantially underlying the dielectric layer, wherein the metal-2 layer is insulated from the metal-1 layer by the dielectric layer; and a back overcoat layer substantially underlying the metal-2 layer.

A method for fabricating a luminescent solar concentrator (LSC) for receiving electromagnetic radiation of at least a first wavelength is disclosed, comprising the steps of: providing a core layer; laminating a lower clad layer to the core layer substantially underlying the core layer; laminating at least one dye layer substantially overlying the core layer, the at least one dye layer having embedded therein at least one absorption dipole and at least one emission dipole, the at least one emission dipole being coupled to the at least one absorption dipole; and at least partially embedding at least one photovoltaic (PV) cell in at least one of the core layer and the lower clad layer, wherein the at least one absorption dipole is configured to absorb the electromagnetic radiation of at least a first wavelength incident from any direction and the at least one emission dipole is configured to emit electromagnetic radiation of at least a second wavelength substantially within at least one of the core layer and the lower clad layer so that the electromagnetic radiation of at least a second wavelength is at least partially absorbed by the at least one PV cell. The at least one absorption dipole is coupled to the at least one emission dipole by Forster resonant energy transfer (FRET). The at least one absorption dipole and the at least one emission dipole are aligned within the at least one dye layer by blending partially miscible dyes within a polymer matrix.

According to an embodiment of the present invention, the method may further comprise laminating an upper clad layer to the at least one dye layer substantially overlying the at least one dye layer. The at least one PV cell may further comprise: an InP substrate of a first conductivity type; a lightly doped InGaAsP base layer of the first conductivity type at least partially underlying the InP substrate; and an InGaAsP emitter layer of a second conductivity type at least partially underlying the lightly doped InGaAsP base layer. The method may further comprise thinning the InP substrate.

According to an embodiment of the present invention, the at least one PV cell may a plurality of PV cells arranged in a sparse hexagonal pattern and interconnected by at least one set of metallic interconnections in a series-parallel configuration to form effectively a single equivalent PV cell.

According to an embodiment of the present invention, the method may further comprise the steps of: depositing a metal-1 and a metal-2 layer substantially underlying the at least one PV cell; depositing a dielectric layer substantially underlying the metal-1 layer; depositing a metal-2 layer substantially underlying the dielectric layer; and depositing a back overcoat layer substantially underlying the metal-2 layer.

### BRIEF DESCRIPTION OF THE DRAWINGS

The present invention will be more readily understood from the detailed description of exemplary embodiments presented below considered in conjunction with the attached drawings, of which:

FIGS. 1A-1C together comprise an exemplary hardware block diagram of a luminescent solar concentrator (LSC) shown at different scales, constructed according to an embodiment of the present invention;

FIG. 2 is a flow diagram depicting energy conversion pathways for a plurality of dye layers depicted in FIG. 1 and grouped by steps of light conversion, energy capture and carrier extraction, according to an embodiment of the present invention;

FIGS. 3A-3C depict the effects of dye dipole alignment on LSC performance with sunlight incident along a coordinate system in which incoming light is received by an LSC waveguide in the z-direction and transmission along the LSC waveguide is oriented in an x-direction;

FIG. 4 depicts various transmission modes within and outside the LSC waveguide of FIG. 1C, according to an embodiment of the present invention;

FIG. 5 is an exemplary hardware block diagram of an evanescently coupled PV cell embedded in a lower clad layer and a core layer, according to an embodiment of the present invention;

FIG. 6 is a schematic diagram of one possible layout for a PV cell array with its interconnects, according to an embodiment of the present invention;

FIG. 7 is an exemplary hardware block diagram depicting the layers of materials comprising the LSC in the vicinity of a PV cell, according to an embodiment of the present invention;

FIG. 8 (Table 1) lists the material types, thicknesses, fill factor, and areal densities of the layers of FIG. 7, according to an embodiment of the present invention; and

FIG. 9 is a flow diagram exhibiting exemplary steps for manufacturing an LSC, according to an embodiment of the present invention.

It is to be understood that the attached drawings are for purposes of illustrating the concepts of the invention and may not be to scale.

### DETAILED DESCRIPTION OF THE INVENTION

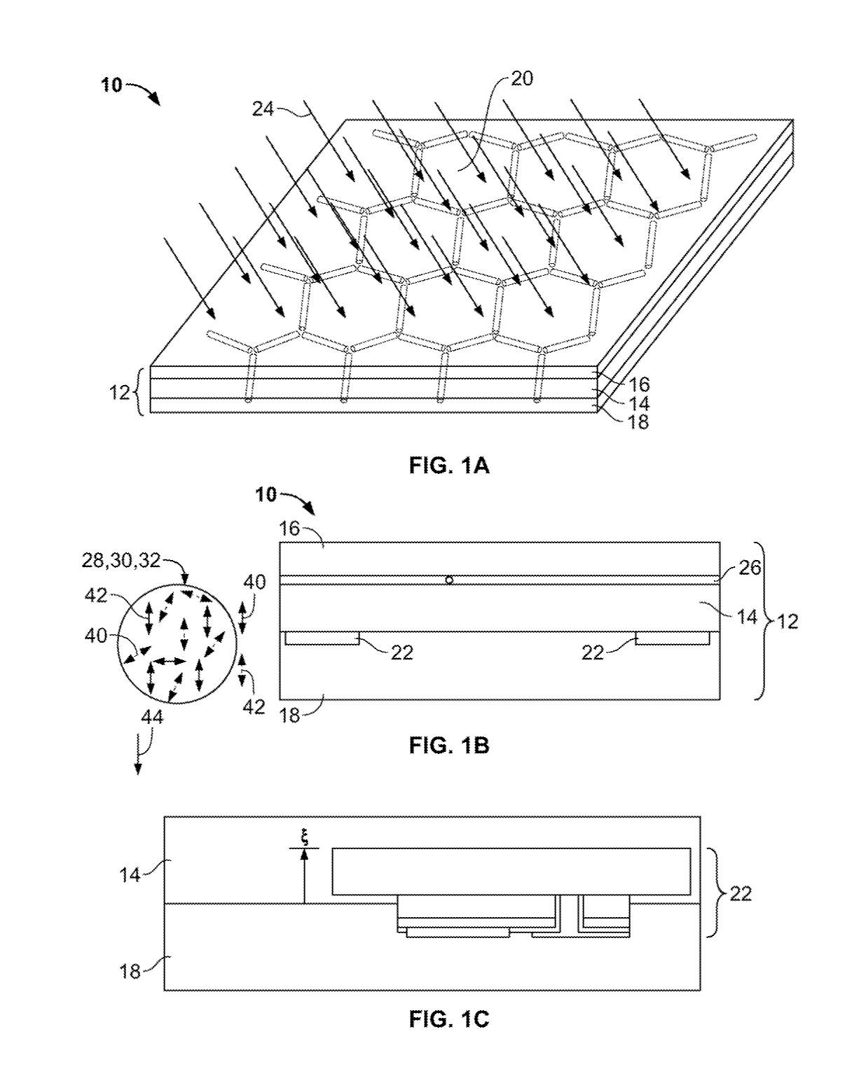

FIGS. 1A-1C together comprise an exemplary hardware block diagram of a luminescent solar concentrator (LSC) shown at different scales, constructed according to an embodiment of the present invention. Referring to FIG. 1A, the LSC 10 is based on efficient light capture and re-emission within a low-loss polymer-based waveguide 12 comprising a polymer core layer 14 overlying and underlying polymer based clad layers 16, 18, the core layer 14 at least partially evanescently and/or edge coupled to a sparse, preferably hexagonal, grid-array 20 of PV cells 22.

As used herein, evanescent coupling in optics refers to a process by which electromagnetic waves are transmitted from one medium to another by means of an exponentially decaying electromagnetic field. Coupling is usually accomplished by placing two or more electromagnetic elements such as optical waveguides close together so that the evanescent field generated by one element does not decay much before it reaches the other element. With waveguides, if the receiving waveguide can support modes of the appropriate frequency, the evanescent field gives rise to propagating wave modes, thereby connecting (or coupling) the wave from one waveguide to the next.

Referring again to FIG. 1A, the hexagonal mesh grid-array 20 permits a scalable architecture where light does not travel more than the long diagonal of a hexagon. Having a clad-core-clad structure for the waveguide 12 keeps most of the guided light away from the surfaces of the waveguide 12 so that most of the light 24 incident on the LSC 10 excites fluorescent light that propagates down the length of the waveguide 12 and does not incur significant losses due to the fluorescent light vertically escaping from the waveguide 12.

Referring now to FIG. 1B, at least one dye layer 26 is located in the core layer 14 and oriented in the plane of the core layer 14 and the clad layers 16, 18. In a preferred embodiment, at least one dye layer 26 comprises a plurality (not shown) of stable, high quantum efficiency dye layers 28, 30, 32 that absorb sunlight incident from any direction and over the solar spectrum from 280 nm-1000 nm and that are aligned to re-emit into the plane of the LSC 10 (i.e., the core layer 14). Each of the plurality of dye layers 28, 30, 32 is sensitive to a particular band of wavelengths (e.g., UV-blue 28, green 30, and red 32) to be described hereinbelow. Each of the plurality of dye layers 28, 30, 32 is doped with a plurality of randomly aligned absorption dipoles 40 that are configured to absorb sunlight incident at any angle and that excite a plurality of aligned emission dipoles 42 by means of Forster resonant energy transfer (FRET). The separate absorption and emission dipoles may be incorporated in separate molecules, which would have the advantage of simplicity, or they may be incorporated as separate functional groups within the same molecule, which would ensure an absorption dipole is always near an emission dipole. Each of the emission dipoles 42 are aligned substantially perpendicular to the plane of the waveguide 12 within the dye layers 28, 30, 32 so that most of the emitted fluorescent light is captured in the waveguide 12 to be described in more detail hereinbelow.

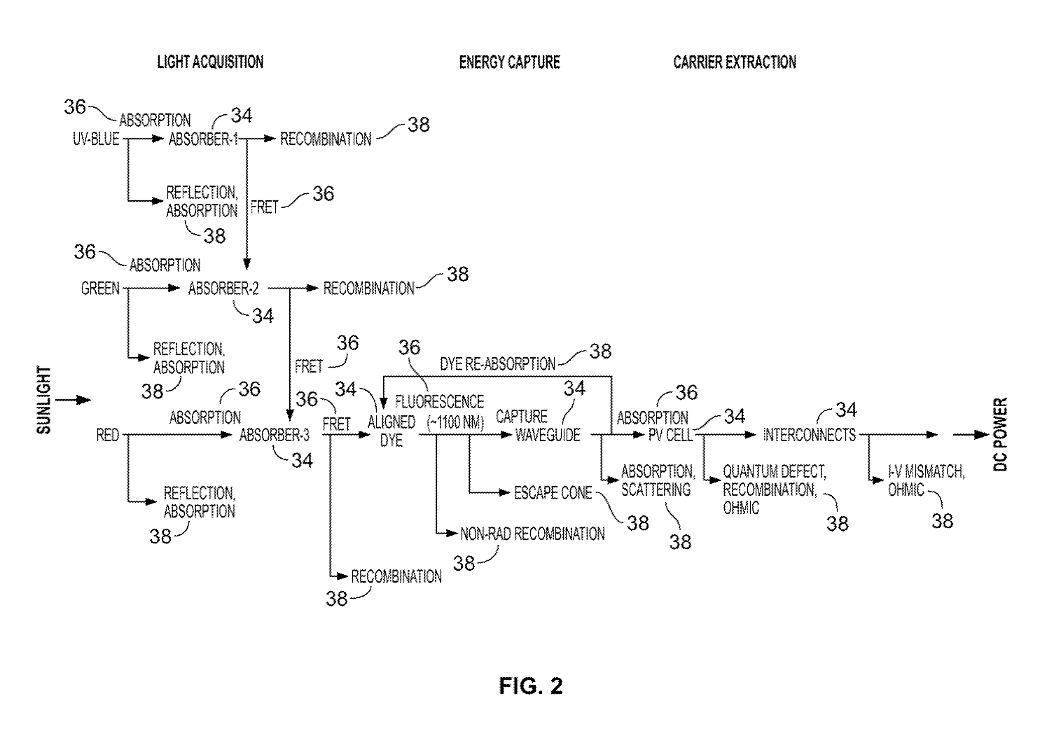

FIG. 2 is a flow diagram depicting energy conversion pathways for the plurality of dye layers 28, 30, 32 of FIG. 1B grouped by energy conversion steps of light conversion, energy capture and carrier extraction, according to an embodiment of the present invention. Elements labeled with reference number 34 denote major components of the LSC 10 (absorber-n, aligned dye, the waveguide 12, the PV cells 22, and interconnects (wiring)). Attributes labeled with reference number 36 (dye absorption, dye fluorescence, FRET, waveguide capture, and PV cell absorption) are maximized, while those attributes labeled with reference number 38 (reflection/absorption, re-absorption, non-radiative recombination, escape cone loss, absorption/scattering, quantum defect, recombination, I-V mismatch) are minimized, according to an embodiment of the present invention.

Referring now to FIGS. 1B and 2, in a preferred embodiment, the UV-blue dye layer 28 absorbs UV/blue light and emits green light (randomly aligned absorption dipoles 40 and FRET-coupling to aligned emission dipoles 42). The green dye layer 30 absorbs green light from the incident sunlight and additionally the emitted green light from the blue layer 28 and emits red light. The red dye layer 32 absorbs red light from the incident sunlight as well as the red light emitted by the green layer 30.

Referring now to FIG. 1C, the energy (fluorescence) propagates in the core layer 14 of the waveguide 12 until it is absorbed by at least one of the sparsely-placed, evanescently and/or butt coupled PV cells 22 located within the waveguide film, forming a hexagonal array. The PV cells 22 capture the fluorescence well before it is lost and concentrate photons from a large collection area to boost the cell open circuit voltage and hence the efficiency of the LSC 10. Evanescent or edge coupling to the array of PV cells 22, rather than traditional butt coupling at the periphery of the LSC 10 permits the PV cells 22 to be located in positions dictated by optimal performance rather than by the form factor of the LSC 10. In a preferred embodiment, the PV cells PV form a hexagon grid with 8 cm sides. In a preferred embodiment, a single hexagon edge may comprise many high aspect ratio PV cells 22 assembled end-to-end. The resulting PV cell areal coverage (fill factor) is about 0.5%, in direct contrast to traditional 100% fill factor modules. (The PV fill factor is the area of the photovoltaic cells divided by the light collection area.)

In a preferred embodiment, the PV cells 22 may comprise InP-based InGaAsP with a bandgap matched to the longest wavelength fluorescence. An InP-based InGaAsP based PV cell has high internal QE and low saturation current density. To work optimally with evanescent coupling, the PV cells 22 may be thinned to below 50 μm which also renders them flexible.

Because the PV cells 22 convert light originating from a larger area than that of the PV cell itself, the light is concentrated. The concentration factor is the ratio of the waveguide transmissivity and the PV fill factor in the LSC 10. This proportionally increases the short circuit current I_{SC} and the open circuit voltage

$${V}_{OC} = \frac{kT}{q} ln ( 1 + {I}_{ph} / {I}_{SAT} )$$

of the PV cells 22, where k is Boltzmann's constant, T is the cell temperature in Kelvin, q is the electron charge, Iₚₕ is the photocurrent and I_{SAT} is the diode saturation current, because the ratio Iₚₕ/I_{SAT} is larger than in unconcentrated schemes. Increasing both I_{SC} and V_{OC} increases the efficiency of the PV cells 22.

Because the absorption dipoles molecules 40 absorb light from any direction equally well, the photo-conversion efficiency (PCE) at non-normal incidence is degraded only by lower photon flux due to lower cross-section overlap with the solar source at that angle and by the reduction in V_{OC} due to the lower flux.

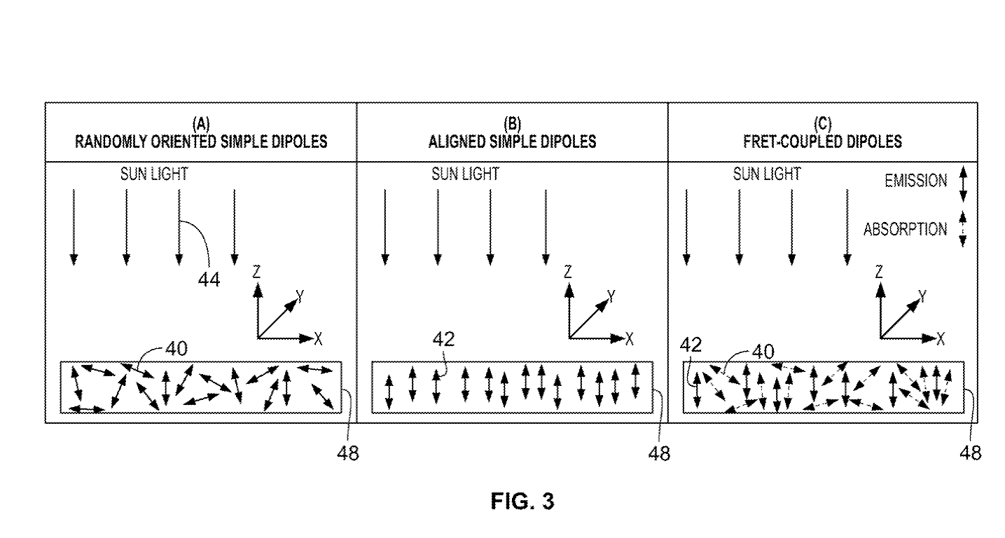

FIGS. 3A-3C depict the effects of dye dipole alignment on LSC performance with sunlight incident along a coordinate system in which incoming light is received by an LSC waveguide 12 in the z-direction and transmission along the LSC waveguide 12 is oriented in the x and y directions. In FIG. 3A, the simple dipoles 40 are oriented randomly with respect to the orientation of a waveguide 48 in the x-z plane. Absorption of photons occurs at all angles of incidence to the waveguide 48 of incoming light 44. Theoretically, about 25% of the photons emitted by randomly distributed embedded dyes in an LSC with an index of refraction of 1.6 are lost in the escape cone, i.e., they are emitted at less than the critical angle for total internal reflection and are not trapped in the LSC.

The loss is greater with a more realistic analysis taking the dipolar nature of the absorption and emission process into account. In a random distribution of the simple dipoles 40, those favorably oriented for emission into the waveguide 48 (i.e., those dipoles aligned along the z-axis) are also the dipoles least excited by near normal incident sunlight while those unfavorably oriented (i.e., those dipoles lying in the x-y plane) are most excited. In FIG. 3B, the simple dipoles 42 are oriented vertically along the z-axis (perpendicularly) with to the orientation of the waveguide 48. The majority of emission by the simple dipoles 42 is normal to the dipole and into the x-direction of the waveguide 48. About 8% of the emitted photons are lost in the escape cone of an LSC with an index of refraction of 1.6. However, there is little absorption of sunlight photons arriving at near-normal incidence, so the overall conversion of sunlight photons to fluorescence photons trapped in the LSC is small.

In FIG. 3C, the simple dipoles 40 employed in certain embodiments of the present invention absorb equally well at all angles of incidence. The simple dipoles 42 emit into the direction of the waveguide along the x-direction. The dipoles 40, 42 are coupled to each other via FRET coupling either in an intermolecular or intramolecular configuration. A dye employing FRET-coupled dipoles 40, 42 have the dual advantages of higher absorption of sunlight and higher coupling of fluorescence into the waveguide. Emission polarized normal to the waveguide from FRET-coupled dipoles 40, 42 provides a third advantage. The only waveguide scattering that results in a loss is scattering into the escape cone (at small angles from the z-axis) to be described hereinbelow. Scattering in this direction has a low cross-section because the polarization of the guided and the scattered light is nearly orthogonal. Thus, the waveguide scattering loss is expected to be very low.

The absorption spectrum of fluorescent dyes is relatively narrow, so it is preferable, according to an embodiment of the present invention, to use three dyes to cover the solar spectrum below 1000 nm. The dyes may be modifications of a common base fluorophore to simplify their design and synthesis. Of the possible strategies for coupling the emission of all three dyes into the waveguide 48, alignment of all three dyes using the strategy of FIG. 3C is preferable because it is the most straightforward and it requires the least amount of dye. It is estimated that a 7 μm film of each dye with 20 without concentration is sufficient to absorb 99% of the sunlight. Back reflection from the PV cell interconnect metal may provide a second pass for the sunlight. Quantum dots seem attractive for LSCs because of their broad absorption spectrum. However, without a permanent dipole moment defining the radiation pattern and with a quantum efficiency (QE) of only 30-50% (compared to >95% for many organic fluorescent dyes), they are not suitable as an alignable dye.

According to certain embodiments of the present invention, there are at least two different two approaches to align a dye within the polymer waveguide. Dye alignment may be effected either through electric field poling or through shearing. In electric field poling, a strong electric field applied to the dye-polymer solution during polymerization will align the dye dipole moment along the electric field. The dyes may also be aligned by applying shear stresses during polymerization, for example, by extrusion or by rolling. These two methods may be used individually or in combination.

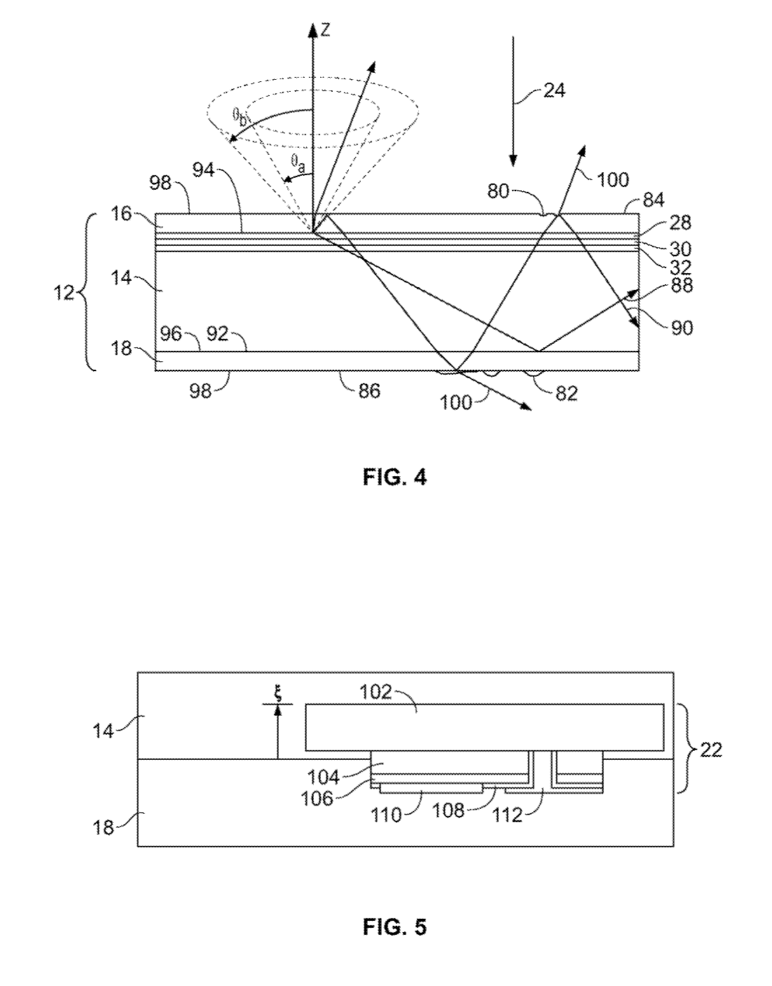

FIG. 4 depicts various transmission modes within and outside the LSC waveguide 12 of FIG. 1C, according to an embodiment of the present invention. The incoming light 24 excites fluorescence from the dye by the process already described. The behavior of a fluorescent photon depends upon its angle of emission relative to a normal (z-axis) to the LSC waveguide 12, the indices of refraction of the core layer 14, the clad layers 16, 18, and the dye layers 28, 30, 32, as well as the presence of incidental scratches 80 and smudges 82 located on one or both of the outer surfaces 84, 86 of the clad layers 16, 18, respectively.

The index of refraction of the dye layers 28, 30, 32 n_{dye} is preferably greater than or equal to that of the core layer 14 to minimize the escape cone loss. The clad layers 16, 18 have an index of refraction of n_{clad}, and the core layer 14 has an index of refraction of n_{core}. The clad layers 16, 18 have a composition such that that they are transparent to the incoming light 24 over a range of wavelengths. At a lower wavelength limit, the upper clad layer 16 needs to be transparent to 280 nm, the short wavelength limit for the AM1.5 spectrum, so that the dye layers 28, 30, 32 may be excited. Polymers such as poly (methylmethacrylate) (PMMA) and Topas® are transparent to this wavelength.

The incoming light 24 into the core layer 14 forms two critical angles, θₐ and θ_{b} with the core layer 14. The first, θₐ=sin⁻(1/n_{core}) or θₐ=sin⁻¹(1/n_{dye}) if n_{dye}>n_{core} defines an escape cone for the entire structure of the LSC 10. Because it is the same as the critical angle of a waveguide without clad layers, the three layer structure does not reduce escape cone losses. Any photon emitting at an angle less than θₐ, will escape and is lost, so it is desirable that n_{core} and n_{dye} be high to minimize escape cone loss. The second critical angle, θ_{b}=sin⁻¹(n_{clad}/n_{core}), separates emitted photons coupling into a waveguide mode 88 and into a substrate mode 90. A photon is trapped only in the core layer 14 for the waveguide mode 88 whereas a photon is trapped in all three layers for the substrate mode 90. The substrate mode 90 is similar to a mode in a standard single layer LSC in that part of the mode is in the ambient air.

The three layer waveguide 12 thus has two populations of trapped photons: those in a waveguide mode 88 and those in a substrate mode 90. The photons in waveguide modes 88 are well protected from the environment by the clad layers 16, 18 because of total internal reflection at a clad-core interface 92. If there were no clad layers 16, 18, the waveguide mode 88 would be more susceptible to losses due to smudges and scratches that accumulate through normal usage on the surfaces 94, 96 of the core layer 14. For indices typical of polymers, n_{core}=1.55 and n_{clad}=1.4, 65% of the trapped light is in the waveguide modes with dye alignment. Photons that may penetrate the clad-core interface 92 in the substrate mode 90 mostly totally internally reflect back into the core layer 14 at an air-clad interface 98, but a very small amount of light may escape 100 at this interface due to the aforementioned scratches 80 and smudges 82, which is much less than would be lost if the clad layers 16, 18 were not present.

The optimal core thickness is determined by the solubility of the dye layers 28, 30, 32, material loss of the waveguide constituents, and the evanescent coupling of light into the PV cells 22. In a preferred embodiment, this thickness may be about 100 μm. Thickness nonuniformity, which is manifested as interfacial roughness with the clad layers 16, 18, may not be critical because it results in scattering losses only if a fluorescent photon is scattered into the escape cone. As already stated, this type of scattering has a small cross-section for fluorescence polarized normal to the LSC plane. The three layer structure also reduces the Fresnel reflection of the light 24. For the above indices, the normal incidence Fresnel reflection loss is reduced from 4.7% without the clad layers 16, 18 to 3.0% with the clad layers 16, 18 assuming that the reflections from the air-clad interface 98 and clad-core interface 92 add incoherently. Thus, certain benefits of the three layer structure include rendering the LSC 10 more robust to handling and reducing the Fresnel losses.

With regard to any effects of the embedded, aligned dye layers 28, 30, 32 on waveguide losses, the largest effect is re-absorption of the fluorescence by a dye layer. The emission spectrum of the two shorter wavelength dye layers 28, 30 may have a large overlap with the absorption spectrum of a longer wavelength dye layer 32 and may be strongly absorbed. With high quantum efficiency and dye alignment, there is a high probability that the energy of an absorbed photon may re-emit as a trapped, longer wavelength photon. The fluorescent energy, in essence, may cascade down to the longest fluorescence wavelength. At this wavelength, absorption occurs only by self-absorption, which is much weaker because of the smaller overlap between the fluorescent and absorption spectra. Self-absorption may be minimized by keeping the concentration of the longest wavelength dye to the minimum needed to absorb the sunlight and the shorter wavelength fluorescence.

Modeling has shown that about a 20% efficiency may be achieved with waveguide losses of 0.09 dB/cm, but losses may be closer to 0.02 dB/cm which may result in the use of fewer PV cells.

According to an embodiment of the present invention, the long wavelength fluorescence may be at about 1100 nm. Unfortunately, hydrocarbon based polymers are less effective near this wavelength because of absorption at overtones of the C—H stretching mode near 900 and 1200 nm. PMMA, a polymer commonly used for light pipes in the visible spectrum, has 0.2 dB/cm of loss because of these overtones, and modeling predicts about a 19% efficiency. A common approach of removing a vibrational absorption peak from a particular wavelength is to shift the peak to longer wavelengths by replacing the hydrogen with fluorine. With no strong absorption peak near 1100 nm, fluoropolymers exhibit low loss in this wavelength regime. Loss due to the matrix in which the dyes are embedded, which may be a different polymer than the rest of the core for chemical reasons, may be minimized by making the dye layers 28, 30, 32 as thin as possible, estimated to be about 7 μm thick each.

Elastic scattering, for example, from density fluctuations in the polymer or from roughness in one of the polymer-polymer interfaces, is a loss mechanism only if the photon scatters into the escape cone. Otherwise, photon scatters into another mode but is not lost. As discussed above, the scattering cross-section of the polarized fluorescence into the escape cone is very small.

FIG. 5 is an exemplary hardware block diagram of an evanescently coupled PV cell 22 embedded in the lower clad layer 18 and the core layer 14, according to an embodiment of the present invention. A thinned n-doped indium phosphide (InP) substrate 102 is embedded substantially in the core layer 14. The InP substrate 102 substantially overlies an n-doped InGaAsP base layer 104 located at least partially in both the core layer 14 and in the lower clad layer 18. The InGaAsP base layer 104 substantially overlies a p doped InGaAsP emitter layer 106 located in the lower clad layer 18. An electrically insulating layer 108 of silicon nitride (SiN) or similar material is located about the doped InGaAsP emitter layer 106 and separates a p doped contact 110 and an n doped contact 112 from the InGaAsP base layer 104 and from each other.

Calculations have shown that the fluorescence center wavelength should be about 1100 nm to collect enough solar photons to achieve 20% efficiency. Although it would be possible to use silicon-based (Si) PV cells, the absorption coefficient of silicon based cells is very low near 1100 nm because 1100 nm is near the band edge of an indirect transition, so that achieving 20% efficiency is unlikely. As a result, in a preferred embodiment, a single crystalline InGaAsP PV cell lattice matched to an InP substrate is employed. InP is a direct bandgap material where the bandgap may be tuned by the composition of the InGaAsP alloy. InP PV cells have achieved 22.1% efficiency under AM1.5 illumination. Having an InGaAsP composition with a bandgap near that of InP is expected to have a similar performance to InP-based solar cells. Calculations have shown an efficiency of 1.2 eV and 1.0 eV bandgap InGaAsP homojunction cells illuminated with a 5000 K blackbody (similar to AM0 illumination) of about 23% and 20.5%, respectively.

Standard LSCs PV cells are rotated 90° and their nominal front surface butted against the edges of a waveguide (i.e., butt coupled). This is difficult to implement and does not scale to larger modules. Certain embodiment of the present invention employ an admixture of evanescent coupling and edge coupling of PV cells 22 to extract energy from the captured fluorescence. For evanescent coupling to be efficient, according to an embodiment of the present invention, the thickness of the core layer 14 should be thinned from the several millimeters as in a standard LSC down to tens of micrometers. In a region of the core layer 14 near the PV cells 22, there are modes with a value of effective index of refraction between the large semiconductor index (i.e., the layers 102, 104, 106) and the polymer core layer 14 index and there are modes with value between the core layer 14 and the lower clad layer 18 indices. Modes in the first group are confined to the semiconductor layers 102, 104, 106 and have large modal absorption coefficients. With a large effective index difference between these modes and those of a bare waveguide, Fresnel reflection may be as large as 10%. Those in the second group extend through both the polymer core layer 14 and the semiconductor layers 102, 104, 106, but have small modal absorption coefficients and small Fresnel reflections. By varying the polymer casting process, the depth ξ of the PV cell that penetrates the core-clad interface may be varied. The bare waveguide modes couple only to the second group for ξ<0 to yield pure evanescent coupling, but are coupled more to the first group as ξ becomes more positive to increase the edge coupling component. The net absorption coefficient for the fluorescent light may increase as ξ increases but so does the Fresnel reflection. The optimum ξ and the net absorption coefficient value at the optimum depends on the details of the design, but the net absorption coefficient can be made to be about 10% of the bulk value for the PV cell absorption layer 104. One way to reduce Fresnel reflections associated with coupling to the first group is by tapering the cell side walls with crystallographic orientation dependent etches, in much the same way texturing is used in commercial Si PV cells. For typical absorption coefficients of 10⁴ cm⁻¹ in direct bandgap semiconductors, the modal absorption length is about 10 μm. How the absorption length impacts the cell design is discussed hereinbelow.

According to a preferred embodiment of the present invention, the PV cells 22 may be sparsely distributed over the LSC 10. A PV cell is an expensive, dense, semi-rigid and puncture-susceptible component, so that reducing cell coverage reduces the module cost, weight, rigidity, and puncture susceptibility. Furthermore, power conversion efficiency increases because the collected solar energy is concentrated into a PV cell 22 over about 0.5% of the collection area. A concentration factor of about 200× without active cooling may be possible because (1) much of the primary source of heat—the quantum defect—occurs at the dye layers 28, 30, 32 and is distributed throughout the LSC 10, and (2) the electrical interconnects contacted to the PV cells 22 also serve as a heat sink that effectively prevents the temperature from building up at the PV cells 22.

The PV cells 22 differ from standard designs in some significant ways. With light evanescently coupled from the polymer waveguide 12, both contacts 110, 112 are located on a side 114 away from the core layer 14. Since the effective absorption coefficient is related to the fraction of light in absorbing layer 104, the PV cells 22 need to be made as thin as possible. The length (lateral dimension along the light propagation direction) of the PV cells 22 should be no longer than that needed to absorb some large fraction of the light. Increasing the length may not increase the short circuit current, but may decrease the short circuit current density and consequently decrease the open circuit voltage. Thus, there is an optimal length for maximizing cell power conversion efficiency that has been determined to be between about 4.5 and 5.2× the absorption length for expected device parameters, yielding a PV cell active length of about 50 μm.

In a preferred embodiment, the array of PV cells 22 may be connected to each other to produce effectively a single module output. According to an embodiment of the present invention, the PV cells 22 may be connected in a series-parallel configuration to build the output voltage to a predetermined value and to reduce I²R losses. In this type of configuration, the PV cells are first formed into identical chains of series-connected cells that are then parallel-connected. Such a configuration works well as long as every cell has an identical output, but a cell with a lower short circuit current—e.g., due to manufacturing variations, component ageing, or non-uniform insolation—may pull the other cells in a series-connected chain away from operating at their maximum power point. The common method to combat this is with a bypass diode connected in parallel but in the opposite polarity with a PV cell or with a chain of PV cells. With the crystalline InGaAsP PV cell employed in a preferred embodiment, a bypass diode may be integrated with each cell by modifying the epitaxial structure and the fabrication steps. Separate bypass diodes that shunt chains of PV cells may be added in an assembly step.

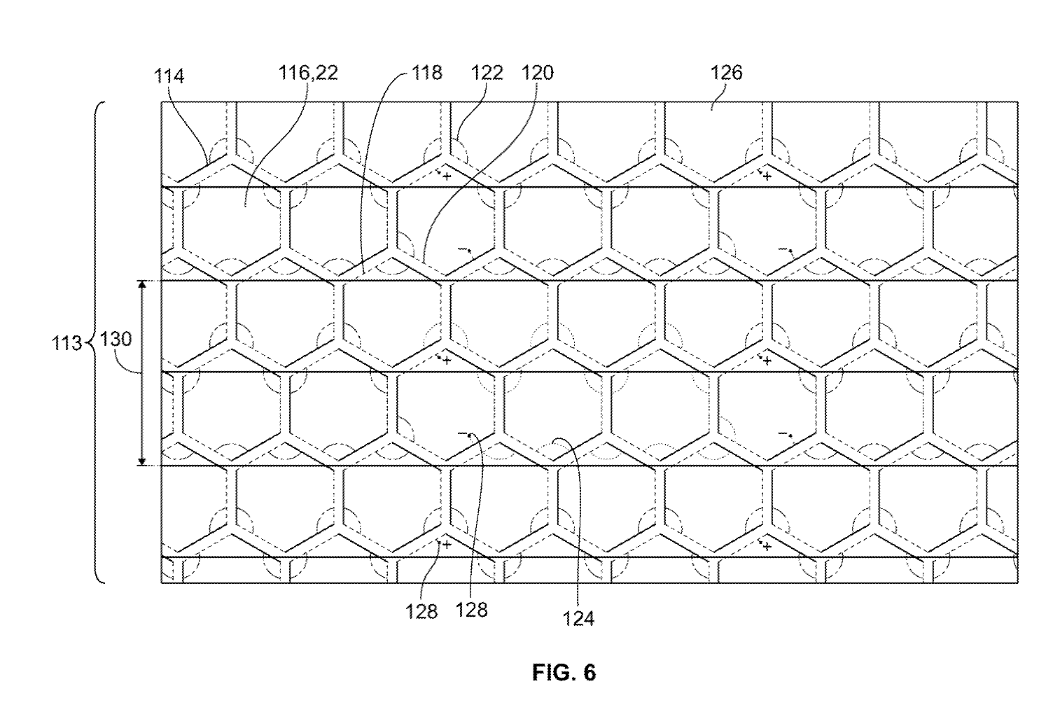

FIG. 6 is a schematic diagram of one possible layout for a PV cell array 113 showing interconnects, according to an embodiment of the present invention. An edge 114 of a hexagon 116 may be about 8 cm in length. The width of the PV cells 22 is exaggerated to provide clarity. The interconnections of the PV cells 22 are indicated as references 118, 120, with reference 118 indicating an n-contact 112 and reference 120 a p-contact 110. Metal-1, which connects the PV cells 22 in a series chain, is indicated as reference 122. One chain is indicated as reference 124 to identify a single chain. Although FIG. 6 shows chains consisting of 18 hexagon edges, the scheme generalizes to chains comprising an integral multiple of 6 hexagon edges. Metal-2, which connects the chains in parallel, is indicated as reference 126. The circles 128 are vias between the two metals 122, 126. Arrows 130 at the left indicate lines that divide the array without breaks in the two metals 122, 126.

The PV cells 22 may be arranged in a mesh pattern that divides the LSC 10 into “corrals” in which photons are confined. The mesh needs to be periodic for scalability, each of the PV cells 22 need to be equivalent so they may be interconnected efficiently, long paths should be avoided, and the cells per area need to be minimized. A mesh that satisfies these constraints is a hexagonal mesh. The cells in the mesh may be interconnected first in series to build up the voltage to the design output voltage and next in parallel to add up the current output of the LSC 10. This is possible because the PV cells 22 are electrically isolated from each other.

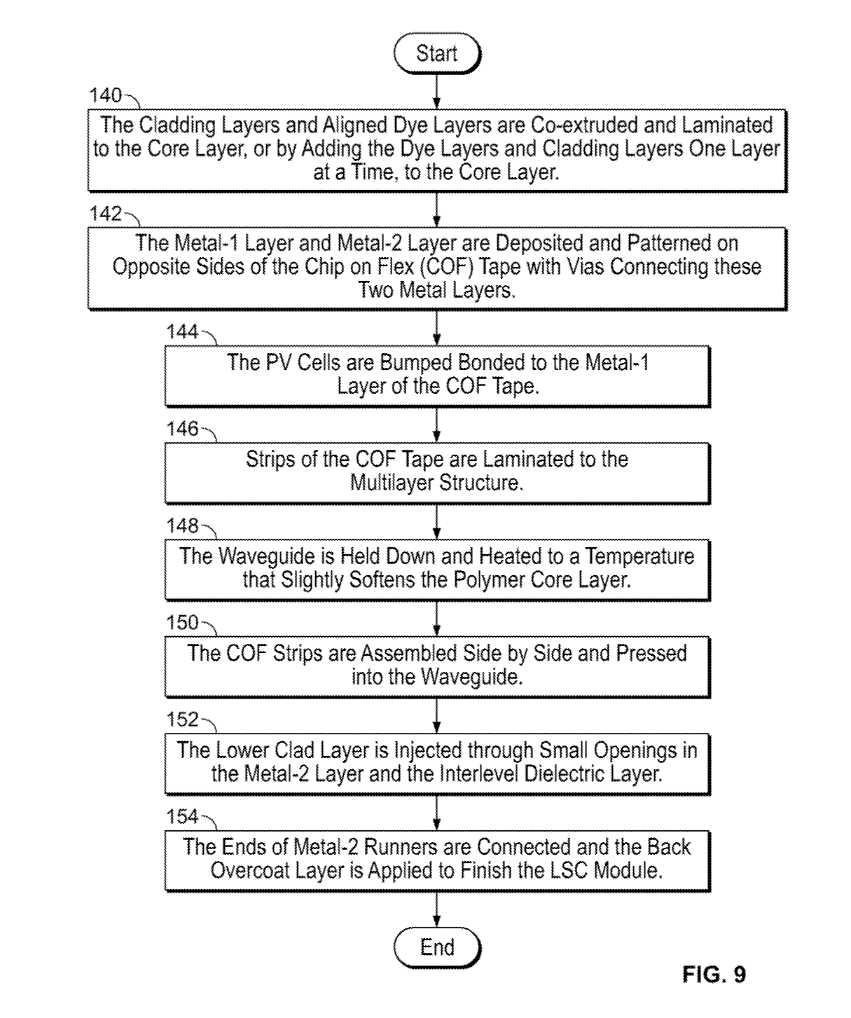

The preferred interconnect scheme is based on two levels of metal shown in FIG. 9. Metal-1 (122) is a local interconnect that connects a chain of cells in series. A chain of 18 cells is shown, but this number is variable. Metal-2 (126) is a global interconnect of thick metal that connects chains in parallel, and may run the width of the array 113. In a preferred embodiment, both metals may be 50 μm Al which may have a sheet resistance of 0.6 mΩ/□. At the edges of the array 130, the Metal-2 stripes may be connected during final assembly to customize the output to high voltage (stripes in series) or high current (in parallel) as well as having two or more independent outputs.

The array 113 may be divided along lines indicated by the arrows in FIG. 9 crossing neither metal nor the PV cells 22. This permits the module be scalable along one dimension. This is also important for assembly, as is discussed hereinbelow. Because metals cover a large fraction of area, they may serve as a reflector to permit sunlight to pass through the dye layers 28, 30, 32 a second time and as a heat sink for the PV cells 22.

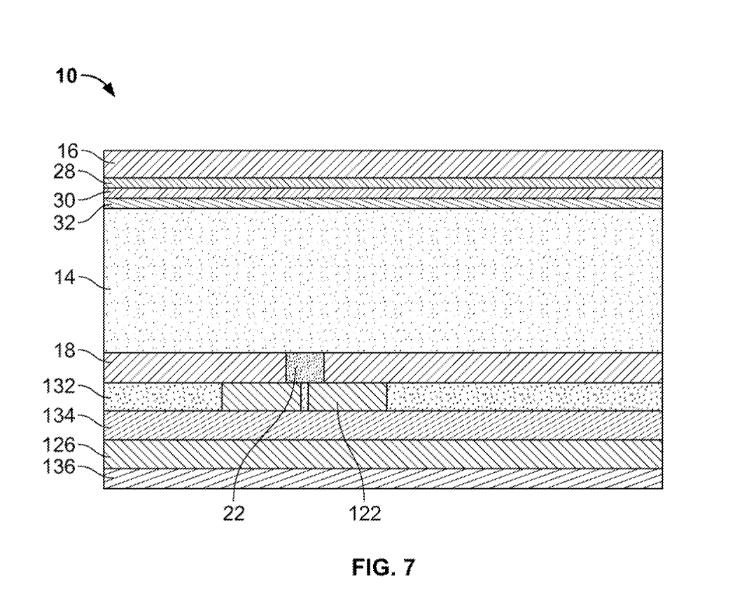

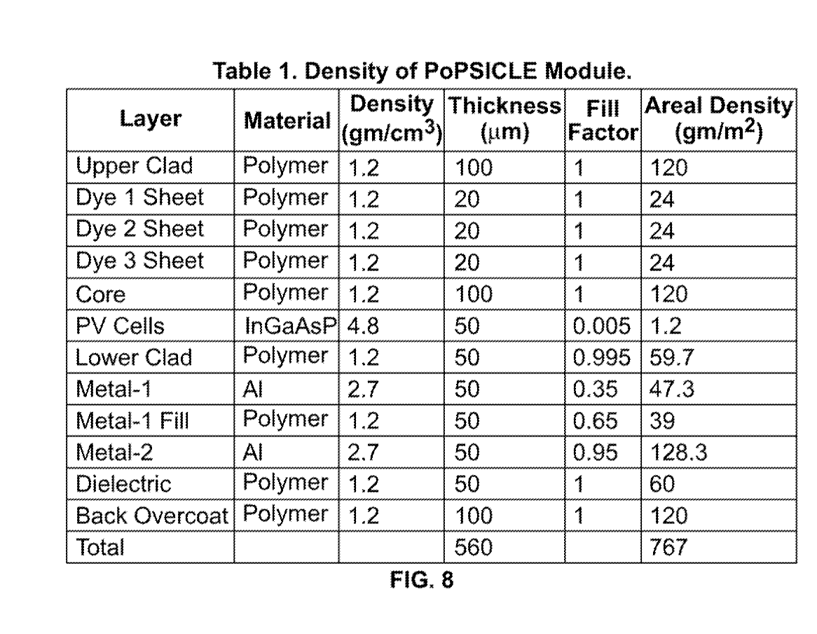

FIG. 7 is an exemplary hardware block diagram depicting the layers of materials comprising the LSC 10 in the vicinity of a PV cell 22, according to an embodiment of the present invention. FIG. 8 (Table 1) lists the material types, thicknesses, fill factor, and areal densities of the layers of FIG. 7, according to an embodiment of the present invention. The LCS 10 may comprise a multilayer polymer film approximately 0.6 mm thick with a sparse array of PV cells 22 distributed throughout the LSC 10 and interconnected with printed wires. The breakdown of the areal density of each layer is given in Table 1. The upper clad layer 16 substantially overlies the plurality of dye layers 28, 30, 32. The plurality of dye layers 28, 30, 32 substantially overlies the core layer 14. The core layer 14 substantially overlies the PV cells 22 and the lower clad layer 18. The metal-1 layer 122 substantially underlies and extends beyond the PV cells 22 and at least partially underlies the lower clad layer 18. A metal-1 fill layer 132 substantially underlies the lower clad layer 18 adjacent to the PV cells 22. The metal-1 layer 122 and the metal-1 fill layer 132 substantially overly a dielectric layer 134, the dielectric layer 134 substantially overlying and electrically insulating the metal-2 layer 126 from the metal-1 layer 122. A back overcoat layer 136 substantially underlies the metal-2 layer 126.

Each of the clad layers 16, 18, the plurality of dye layers 28, 30, 32, the core layer 14, the metal-1 fill layer 132, the dielectric layer 134, and the back overcoat layer 136 are polymer-based, while the metal-1 layer 122 and the metal-2 layer 126 are preferably made of, but not limited to, aluminum. The upper clad layer 16, the core layer 14, and the back overcoat layer 136 are each preferably about 100 μm in thickness, while the lower clad layer 18, the PV cells 22, the lower clad layer 18, the metal-1 layer 122, the metal-2 layer 126, the metal-1 fill layer 132, and the dielectric layer 134 are about 50 μm in thickness. The dye layers 28; 30, 32 are each about 20 μm in thickness. Thus, the overall thickness of the LSC 10 is more precisely about 560 μm with an areal density of about 767 gm/m².

The effects of a 2 mm diameter puncture on an LSC module comprising a hexagonal mesh with 8 cm edges have been estimated. All wiring had widths much larger than 2 mm, and were thus not affected by the puncture. Each edge was made of eight, 1 cm long PV cells. Based on relative areas, the probability of destroying exactly one cell was about 0.017, the probability of destroying exactly two cells was about 0.012, and the probability that the puncture was near the vertex and destroys all three cells was about 6.3×10⁻⁵. Since there may be 1440 cells in a 1 m² LSC module, the expected degradation of the module is about 1.2×10⁻⁵, 1.6×10⁻⁵ and 1.3×10⁻⁷, respectively, for hitting 1, 2 and 3 PV cell.

if a puncture misses a cell, the main degradation is the loss of light when it encounters the puncture. The expected degradation was estimated by considering that when a dye molecule emits a photon into the waveguide, the photon may propagate in any of 2π radians before encountering a PV cell. A hole spans an angle d/R to the dye, where d is the diameter of the hole and R is the distance between the dye and the hole. The probability that the photon is lost is d/2πR. The output for that hexagon is reduced by d/4πR, where the extra factor of 2 comes about because an equal flux of photons is arriving from the adjacent hexagons. Taking R on average to be half the length of the edge, the expected degradation is about 3.2×10⁻² for the affected hexagon, and 5.3×10⁻⁴ for the LSC module. Summing all over all the possible places the puncture may land gives an expected module output degradation of 1.1×10⁻³ for a single 2 mm diameter puncture. Since the puncture area is a very small fraction of the module area, the degradation of several punctures is additive.

Contrary to initial impressions that all dyes are short-lived, long-lived fluorescent films (e.g., 3M Fluorescent Reflective Sheeting) with years of life may be used in outdoor signage applications.

In conventional SCs, one limit on the concentration ratio is the heating of the cells. The LSC 10 of the present invention has an advantage in that most of the quantum defect loss, which is the main PV cell heating mechanism, occurs throughout the LSC 10 rather than only in the PV cells 22. For a 1 m² LSC module under 1000 W AM1.5 input, modeling has shown about 723 W absorbed by the dye layers 28, 30, 32. Of this, 201 W is converted to electricity, 63 W is lost through the escape cone, 308 W is dissipated in the LSC 10, and 151 W is dissipated by the PV cells 22. The power dissipated by each cell is 1.1 W or 3.4 W/cm², which is handled by passive cooling in integrated circuits.

The flexibility of the three types of components that may be used in an LSC has been evaluated for InGaAsP on InP, polymers and Al interconnects. Of greatest concern was the InGaAsP on InP because its failure mechanism is fracture. The InGaAsP PV cells were thinned to 50 μm or less. The effect of a 3 cm radius of curvature was estimated. The bending stress σ_{B} for a film of thickness d=50 μm bent to a radius of R=3 cm was about σ_{B}=Ed/2R(1−v²)=58 MPa, where E=61 GPa is the Young's modulus and v=0.36 is Poisson's ratio. The PV cell was not at the neutral plane, but about 45 μm below it (See Table 1). To estimate the bending stress at this level, the distance to the neutral plane may be added to the thickness, which raises the bending stress to about 100 MPa. The strength of InP has been shown to have a fracture probability of 0.0001 for less than 100 MPa bending stress.

The major LSC components are polymers. Using the mechanical properties of PMMA as representative (E=3 GPa, v=0.4), a bending stress was obtained for a d=500 μm film and bent to a radius R=3 cm of 30 MPa. The resulting bending strength was about 120 MPa, so an LSC may be safely bent. Finally, the aluminum interconnects were considered. A similar analysis for 50 μm of Al gives a bending stress of about 70 MPa. Comparing this to the yield strength of 215 MPa, it may be concluded that the Al may be safely bent.

FIG. 9 is a flow diagram exhibiting exemplary steps for manufacturing an LSC, according to an embodiment of the present invention. The initial process begins with the central, low-loss, polymer, waveguide core layer 14. At step 140, subsequent films composing the cladding layers 16, 18 and aligned dye polymer film layers 28, 30, 32 may be co-extruded and laminated to the core layer 14 or by adding the dye layers 28, 30, 32 and cladding layers 16, 18, one layer at a time, to the thicker core layer 14 after the core layer 14 has been extruded and cast. This requires less complex equipment than simultaneous co-extrusion and casting of the multiple layers, although multilayer co-extrusion and casting may be lower in cost in a manufacturing operation. A roll-coater may be used to affix the dye layers and upper cladding to the core.

So that the PV cells 22 may be easily integrated with the sheets, the PV cells 22 may be affixed to a chip on flex (COF) tape by a vendor such as Aspen Technologies. The COF tape may be built on a polymer substrate such as Kapton. At step 142, the Metal-1 layer 122 and the Metal-2 layer 126 may be deposited and patterned on opposite sides of the Kapton tape with vias connecting the two metal layers 122, 126 and with the Kapton as the interlevel dielectric 134. At step 144, the previously fabricated, thinned and diced PV cells 22 may be bump bonded to the Metal-1 layer 122 of the COF tape. The bypass diodes that shunt a chain of the PV cells 22 may also be bump bonded. The module may be divided along the gaps shown by the arrows in FIG. 9 where neither metal crosses and where the PV cell mesh may be separated. Thus, the tape may have the PV cells 22, the metal-1 layer 122, the metal-2 layer 126 and the dielectric layer 134 (Kapton). At step 146, strips of the COF tape may be laminated to the multilayer waveguide structure. At step 148, an assembly jig comprising a vacuum platen with heater and temperature controller may be used to hold down the waveguide 12 and heat it to a temperature that slightly softens the polymer core layer 14. At step 150, the COF strips may be assembled side by side, like wallpaper, and pressed into the waveguide using a soft pressure plate, or possibly a pressurized air bladder for uniform, controllable pressure. This pressure may be used to adjust the parameter ξ in FIG. 5.

At step 152, the lower clad layer 18 (See FIG. 7), which may be the same polymer as the upper clad layer 16, may be injected through small openings in the metal-2 layer 132 and the Kapton interlevel dielectric layer 134 to fill gaps in the structure. (The thickness of the cladding layers 16, 18 is not critical). After the lower clad layer 18 is polymerized, the COF tape with the PV cells is firmly attached to the waveguide laminate. Larger values of the parameter ξ in FIG. 5 than can be achieved by pressure may be obtained by first injecting and polymerizing a layer of the core polymer followed by injecting and polymerizing the lower clad polymer. Finally, at step 154, the ends of metal-2 runners may be connected and the back overcoat layer 136, which insulates the metal-2 layer 126 may be applied to finish the LSC module 10.

It is to be understood that the exemplary embodiments are merely illustrative of the invention and that many variations of the above-described embodiments may be devised by one skilled in the art without departing from the scope of the invention. It is therefore intended that all such variations be included within the scope of the following claims and their equivalents.

1. A luminescent solar concentrator (LSC) for receiving electromagnetic radiation of at least a first wavelength, comprising:
a core layer;
a lower clad layer substantially underlying the core layer;
at least one photovoltaic (PV) cell partially embedded in at least one of the core layer and the lower clad layer; and
at least one dye layer substantially overlying the core layer, the at least one dye layer having embedded therein at least one absorption dipole and at least one emission dipole, the at least one emission dipole being coupled to the at least one absorption dipole;
wherein the at least one absorption dipole is configured to absorb the electromagnetic radiation of at least a first wavelength incident from any direction and the at least one emission dipole is configured to emit electromagnetic radiation of at least a second wavelength substantially within at least one of the core layer and the lower clad layer so that the electromagnetic radiation of at least a second wavelength is at least partially absorbed by the at least one PV cell.

2. The LSC of claim 1, wherein the at least one absorption dipole is coupled to the at least one emission dipole by Forster resonant energy transfer (FRET).

3. The LSC of claim 1, wherein the at least one emission dipole is aligned substantially perpendicular to a plane of stacking of the core layer, at least one dye layer, and the lower clad layer.

4. The LSC of claim 1, wherein the at least one absorption dipole is substantially randomly aligned to a plane of stacking of the core layer, the at least one dye layer, and the lower clad layer.

5. The LSC of claim 1, wherein the at least one dye layer comprises a plurality of dye layers that are sensitive to non-overlapping bands of electromagnetic radiation.

6. The LSC of claim 5, wherein dipole dye molecules embedded within one of the plurality of dye layers are configured to emit a wavelength of electromagnetic radiation that is within an absorption band of dipole dye molecules embedded within a successive layer of the plurality of dye layers.

7. The LSC of claim 5, wherein the plurality of dye layers comprises at least a UV-blue absorbing layer, a green absorbing layer, and a red absorbing layer.

8. The LSC of claim 1, further comprising an upper clad layer substantially overlying the at least one dye layer.

9. The LSC of claim 8, wherein the upper clad layer, the at least one dye layer, the core layer, and the lower clad layer have indices of refraction set to predetermined values such that the emitted electromagnetic radiation of at least a second wavelength is substantially confined within the core layer.

10. The LSC of claim 8, wherein at least one of the upper clad layer, the at least one dye layer, the core layer, and the lower clad layer is composed of fluorinated polymers.

11. The LSC of claim 1, wherein at least one of the core layer and the lower clad layer is configured to at least one of evanescently couple and edge couple the emitted electromagnetic radiation of at least the second wavelength to the PV cell.

12. The LSC of claim 1, wherein the at least one PV cell is InP—InGaAsP based.

13. The LSC of claim 12, wherein the at least one PV cell further comprises:
an InP substrate of a first conductivity type;
a lightly doped InGaAsP base layer of the first conductivity type at least partially underlying the InP substrate; and
an InGaAsP emitter layer of a second conductivity type at least partially underlying the lightly doped InGaAsP base layer.

14. The LSC of claim 13, wherein the InP substrate is thinned.

15. The LSC of claim 8, wherein the at least one PV cell is a plurality of PV cells arranged in a sparse hexagonal pattern and interconnected by at least one set of metallic interconnections in a series-parallel configuration to form effectively a single equivalent PV cell.

16. The LSC of claim 15, wherein the series-parallel configuration includes at least one chain of PV cells having at least one bypass diode to allow the chain of PV cells to operate at its maximum power point.

17. The LSC of claim 9, further comprising:
a metal-1 layer substantially underlying the at least one PV cell and at least partially underlying the lower clad layer;
a metal-1 fill layer substantially underlying the lower clad layer adjacent to the at least one PV cell;
a dielectric layer substantially underlying the metal-1 layer,
a metal-2 layer substantially underlying the dielectric layer, wherein the metal-2 layer is insulated from the metal-1 layer by the dielectric layer; and
a back overcoat layer substantially underlying the metal-2 layer.

18. A method for fabricating a luminescent solar concentrator (LSC) for receiving electromagnetic radiation of at least a first wavelength, comprising the steps of:
providing a core layer;
laminating a lower clad layer to the core layer substantially underlying the core layer;
laminating at least one dye layer substantially overlying the core layer, the at least one dye layer having embedded therein at least one absorption dipole and at least one emission dipole, the at least one emission dipole being coupled to the at least one absorption dipole; and
at least partially embedding at least one photovoltaic (PV) cell in at least one of the core layer and the lower clad layer,
wherein the at least one absorption dipole is configured to absorb the electromagnetic radiation of at least a first wavelength incident from any direction and the at least one emission dipole is configured to emit electromagnetic radiation of at least a second wavelength substantially within at least one of the core layer and the lower clad layer so that the electromagnetic radiation of at least a second wavelength is at least partially absorbed by the at least one PV cell.

19. The method of claim 18, wherein the at least one absorption dipole is coupled to the at least one emission dipole by Forster resonant energy transfer (FRET).

20. The method of claim 18, wherein the at least one emission dipole is aligned substantially perpendicular to a plane of stacking of the core layer, at least one dye layer, and the lower clad layer.

21. The method of claim 18, wherein the at least one absorption dipole is substantially randomly aligned to a plane of stacking of the core layer, the at least one dye layer, and the lower clad layer.

22. The method of claim 18, wherein the at least one absorption dipole and the at least one emission dipole are aligned within the at least one dye layer by mixing dyes within a polymer matrix to produce a dye-polymer solution and by applying an electric field or sheer stress to the dye-polymer solution.

23. The method of claim 18, further comprising laminating an upper clad layer to the at least one dye layer substantially overlying the at least one dye layer.

24. The method of claim 18, wherein the at least one PV cell further comprises:
an InP substrate of a first conductivity type;
a lightly doped InGaAsP base layer of the first conductivity type at least partially underlying the InP substrate; and
an InGaAsP emitter layer of a second conductivity type at least partially underlying the lightly doped InGaAsP base layer.

25. The method of claim 24, further comprising the step of thinning the InP substrate.

26. The method of claim 18, wherein the at least one PV cell is a plurality of PV cells and further comprising the step of arranging the plurality of PV cells in a sparse hexagonal pattern and interconnecting the plurality of PV cells by at least one set of metallic interconnections in a series-parallel configuration to form effectively a single equivalent PV cell.

27. The method of claim 25, further comprising the steps of:
depositing a metal-1 layer substantially underlying the at least one PV cell;
depositing a dielectric layer substantially underlying the metal-1 layer;
depositing a metal-2 layer substantially underlying the dielectric layer; and
depositing a back overcoat layer substantially underlying the metal-2 layer.
